(19) United States
(12) Patent Application Publication
(10) Pub. No.: US 2024/0348085 A1
(43) Pub. Date: Oct. 17, 2024

(54) DISAGGREGATION AND LOAD IDENTIFICATION OF LOAD-LEVEL ELECTRICAL CONSUMPTION FOR AUTOMATED LOADS

(71) Applicant: EATON INTELLIGENT POWER LTD., Dublin (IE)

(72) Inventors: Niall CAHILL, Dublin Dublin (IE); Keith NOLAN, Westmeath (IE)

(21) Appl. No.: 18/292,085

(22) PCT Filed: Jul. 27, 2021
(86) PCT No.: PCT/EP2021/071004

§ 371 Date: Jan. 25, 2024

(51) Int. Cl. H02J 13/00

(52) U.S. Cl. CPC H02J 13/00002

(57) ABSTRACT

A disaggregation and identification method arranged to disaggregate and identify aggregated electrical load data. The method comprises obtaining operation data from an automated control management system; extracting a timing sequence from the operation data for each load in the automated system; storing each timing sequence in a datastore; streaming aggregated power data from a load center associated with the system, wherein the power data comprises measured electrical signals; and recording time stamps for each new event measured from the streamed aggregated power data, wherein an event is a change in power signal at a load. The method further comprises performing nearest neighbour comparison of the recorded power time series data to the timing sequence of the operation data; mapping each event timestamp to the nearest time sequence; classifying the load according to the mapped time data; and storing the classified load profile in a datastore.

### FIELD OF INVENTION

The field of this invention relates to disaggregating electrical data from automated loads within a large power system, identifying the particular load of a particular device associated with the disaggregated signal, and obtaining load-level electrical power consumption for each load.

### BACKGROUND

Optimising power systems has become a prominent focus in recent years in order to improve the efficiency, cost, and power requirements of such systems. Determining the relationship between different signals from different devices within the power system network allows for the optimisation of such systems to be achieved. Various benefits can be gained by collating all the signal information of a power system and depending on the application can lead to a more advanced control of certain devices. An example of such a system is the PowerGenome architecture of Eaton, where the assembly of all measured data within the system is compiled into a single database. However, in order to optimise such a system, like PowerGenome, large amounts of data need to be collected from a plurality of different sources. Typically, in a PowerGenome-type application a plurality of different signals are measured at each of the plurality of devices connected within the system. These signals are typically recorded as high-resolution raw data from measurements taken by, for example, a sensor device and collated together in order to establish relationships between the devices within the system.

PowerGenome-type architectures can be adopted into industrial environments, where a large number of machines and devices are connected and controlled by a centralised system. For example, common applications include manufacturing processes, building environments automated production lines and other large scale projects. Obtaining, analysing and modelling the data of these centralised systems is of great importance for optimisation purposes. The Building Management System (BMS) is a known computer-based control system which is installed in buildings and centrally controls the mechanical and electrical equipment of the building. The BMS comprises software which communicates with each of the system components, i.e. the mechanical and electrical equipment, providing automated control and scheduling of these components. This automation is often implemented via Programmable Logic Controllers which control the components of the system. The PLCs can be programmed in a variety of ways depending on the application, i.e. in a relay-type fashion, and are usually programmed using ladder logic programming language. Automating components of such systems is known to have a variety of results depending on the application, such as improve building efficiency, save energy, increase production efficiency and improve security.

Further, these centralised control systems are becoming increasingly common in domestic settings with the emergence of Internet of Things (IoT) based devices. As such, an increasing number of devices and domestic appliances have network capabilities, along with sensors and other software to enable them to communicate over a network such as the Internet. Thus, these devices may be automated and controlled from a centralised system, such as an application on a mobile device, to create an automated “smart” home.

However, the problem lies when trying to distinguish and attribute the various signals to each of the plurality of devices within a large multiple aggregated load system, especially when the system is automated. This is difficult as circuit-level measurements of a device, such as current and voltage load signals, are often an aggregation of multiple load signatures. This is especially difficult when multiple signals are occurring at the same time from a wide range of potential loads that could be connected to the circuit. Analysing each of the individual loads of each device connected in a multiple aggregated load system is a challenge and can be a laborious task when trying to disaggregate the signals from the combined data. Existing approaches attempt to automatically disaggregate and classify the signals using AI techniques with varying level of accuracy. These techniques require exhaustive training and testing in order to identify and label certain aspects of the data. Disaggregation and load identification from aggregated voltage and current signals is a key capability for realising the use of data in an intelligent way, as for example Eaton's Power Genome. In general, disaggregation and load identification is a pre-requisite process for important applications such as predictive maintenance and digital health.

This disclosure is directed at the provision of a method and system for disaggregating raw data signals in an automated system in order to identify the load and the load-level electrical consumption. In particular, mapping high-level automation control information to a measured aggregated electrical power consumption, such as combined current and voltage waveforms, from a plurality of electronic devices.

### SUMMARY

The challenge of disaggregating the load signals as described above is addressed by the present invention. This invention utilises the timing sequences from the automated control management system to map the recorded aggregated load signals to the individual load. Namely, using nearest neighbour analysis a recorded load event, which has a recorded timestamp, is attributed to one or more timing sequences of the control management data, providing the necessary information to identify the load responsible for the event signal. Thus, the aggregated signal is disaggregated, the load is identified and the corresponding electrical consumption is obtained.

In a preferred embodiment of the present invention there is provided a disaggregation and identification method arranged to disaggregate and identify aggregated electrical load data, comprising the steps of: obtaining operation data from an automated control management system; extracting a timing sequence from the operation data for each load in the automated system; storing each timing sequence in a datastore; streaming aggregated power data from a load centre associated with the system, wherein the power data comprises measured electrical signals; recording time stamps for each new event measured from the streamed aggregated power data, wherein an event is a change in power signal at a load; performing nearest neighbour comparison of the recorded power time series data to the timing sequence of the operation data; mapping each event timestamp to the nearest time sequence; classifying the load according to the mapped time data; and storing the classified load profile in a datastore.

The automated control management system may be a ladder logic program, controlling a plurality of programmable logic controllers (PLCs).

The loads may be controlled from the load centre based on an automated schedule of aggregated signals.

The load centre may be connected to a plurality of loads connected to the same circuit.

The loads are associated with industrial or domestic devices.

The load centre may capture the current and voltage signals of the connected loads.

Each recorded event may be within an event threshold.

A classification threshold may be used to avoid spurious associations.

The datastore may be located locally at system level.

The datastore may be located remotely on a remote server or cloud, or the like.

The load profiles may be analysed in at the time of acquisition or at a later date.

In a preferred embodiment of the present invention there is provided a disaggregation and identification system comprising: a processor; an automated control management system; a load centre; and a datastore, wherein the processor is configured to disaggregate and identify load data from an aggregated electrical signal.

### BRIEF DESCRIPTION OF THE DRAWINGS

The disclosure will be described, by way of example only, with reference to the accompanying drawings, in which:

FIG. 1 is a diagram of a power system comprising a plurality of connected loads, wherein the loads are controlled by a control management system;

FIG. 2 is a ladder logic diagram of logic control programming, wherein the program is implemented into the control management system to control and schedule the outputs of the connected loads; and

FIG. 3 is a flow diagram of the disaggregation and load identification method of the present disclosure.

### DETAILED DESCRIPTION

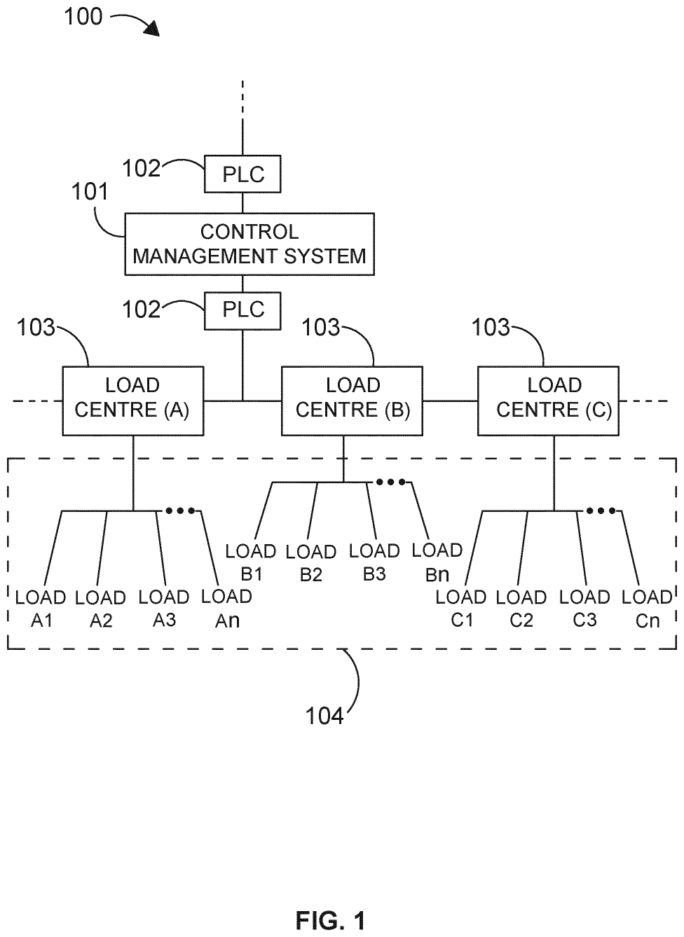

FIG. 1 is an example schematic diagram of a power system 100 comprising a plurality of connected loads 104, wherein the loads 104 are controlled by a control management system 101 via one or more Programmable Logic Controllers (PLC) 102. The connected loads 104 may be connected straight to the control management system 102 or may be connected via a load centre 103 depending on the system architecture and/or the application, i.e. building environment management, assembly line management, etc. The control management system 101 is configured to stream and gather power data from the load centres 103, which are connected to a PLC 102. The streaming of the power data can also be performed by an external device connected into the system 100. As each load 104 is connected to the same circuit, the current and voltage signals of the combined loads 104 are captured by the control management system 101 or external device, thus resulting in an aggregated power signal. In a large industrial manufacturing setting this can be as much as 100 or more loads connected. For example, a manufacturing cell can contain multiple automated loads associated with conveyor belts, pumps, robotic arms, cutting machines, packing machines, etc.

In a domestic setting the power data can be streamed from circuit breakers embedded or attached to each of the domestic device or appliance. Most circuit breakers have sensors and network capabilities for measuring and transmitting the power data. The aggregated power signals of such connected appliances can be streamed via the electrical supply point, i.e. the electrical point of entry or switch box, within a house.

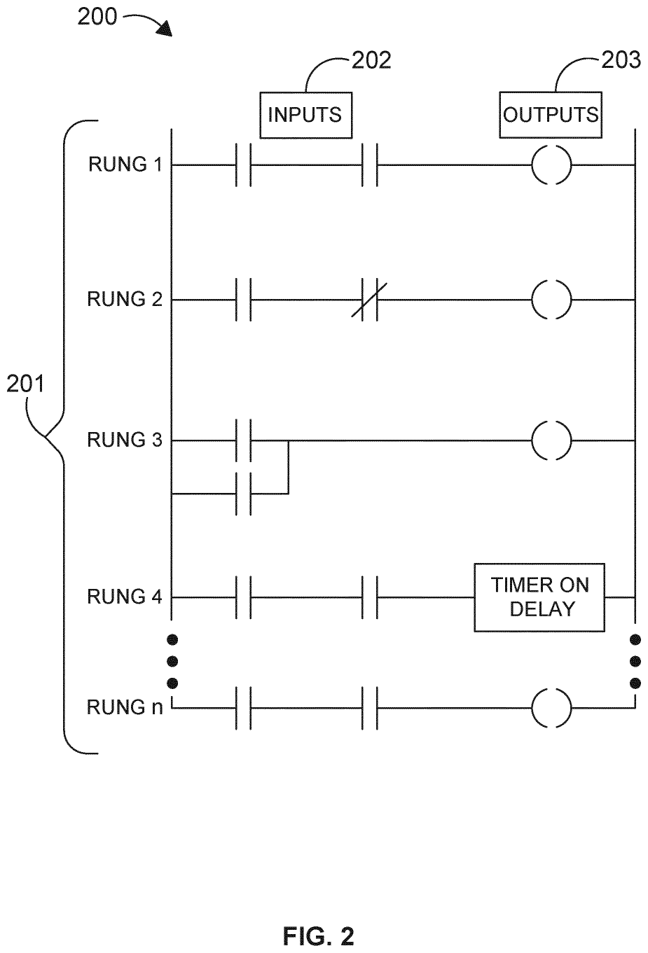

FIG. 2 is an example ladder logic diagram 200 of logic control programming. The program is implemented into the control management system 101 to control and schedule the outputs 203 of the connected components, i.e. connected loads 104. Each rung 201 in the ladder logic diagram 200 can correspond to a particular load 104 or one or more synchronised loads within a particular device, depending on the function of the device. The program is downloaded to the PLC 102 directly from the control management system 101 or from external sources, such as a personal computer, over a network. The program is stored in an appropriate memory within the PLC 102. Typically a rung 201 represents a rule in the program that runs left to right across “the ladder”. When executed on the PLC the program performs a function on the relays and/or devices which have been assigned to the particular rung(s) 201. The function depends on the conditions at the inputs 202 and outputs 203, where the outputs 203 represent a physical output which operates some device connected to the PLC. For example, load A1 may be assigned to rung 1 and be programmed to function at a specific time, while load A2 is assigned to rung 2 and is programmed to be inactive while load A1 is inactive. This is a very simple example. The skilled person will realised that the ladder logic program can control very complex systems and have multiple loads operating concurrently or sequentially, or both.

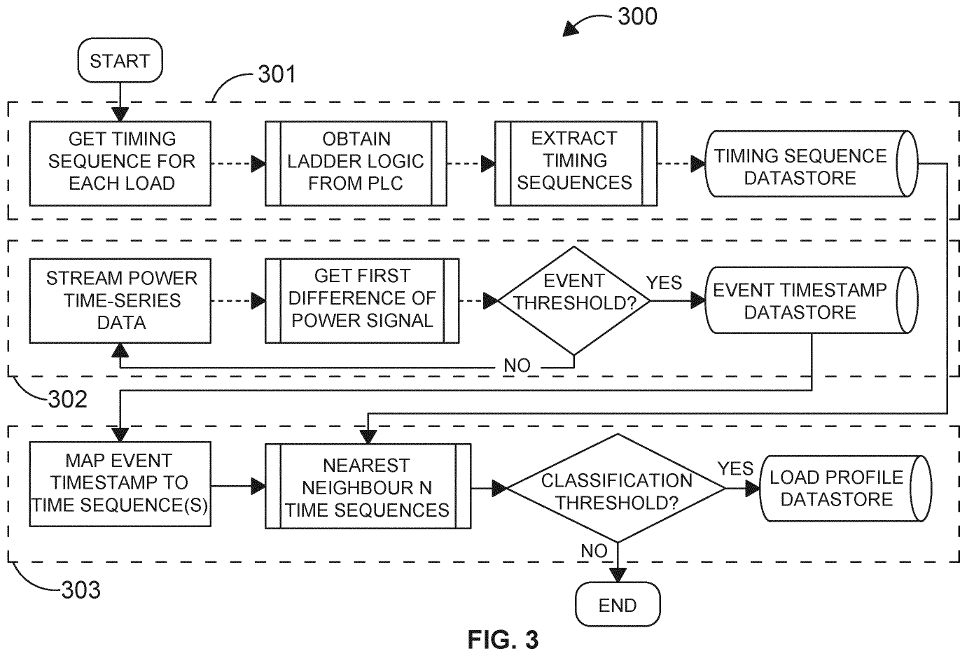

FIG. 3 is an illustration of a flow diagram of the disaggregation and load identification process 300 of the present invention, with three key steps. The first step 301 is to obtain the timing sequence for each load. The timing sequences are extracted from the ladder logic program 200 for each load 104 and are stored in a database. The database may be stored locally in a timing sequence datastore of the control management system 101 or remotely in a remote server or cloud. Storing the extracted data and implementing the disaggregation and load identification method remotely allows any data analysis, system optimisation and device monitoring to be carried out off site. The same principle applies to domestic IoT devices and appliances.

The second step 302 of the method, as illustrated in the flow diagram 300, comprises streaming the aggregated power signals from the load centre. These signals can be streamed to a local datastore within the control management system or to a remote server. The aggregated power signals can be gathered either at full system level or circuit level, i.e. building/factory wide or at each device/machine. The data of the aggregated power signals is recorded as a time-series such that, at t₁ a measured current I₁ and voltage V₁ value is recorded, and at t₂ a second current I₂ and voltage V₂ is recorded, etc. The current and voltage may be measured at the load centre by one or more sensors, circuit breakers or any other suitable measurement devices. The streamed power time-series data is analysed to determine any occurrences of an event within the recorded time period. An event is a change in power signal at the load or load centre.

From the streamed power data, take the first difference recorded in the power signal, i.e. if the measured current value at t₁ differs from the value at t₁. The difference in power signal is compared with a threshold, for example >10 Amps. For high power electronics this threshold may be significantly higher. As such, the threshold value may be selected depending on the application of the loads and the information that is to be gained from the power system. A simple example may be thought of as a user requiring information about a particular load within a circuit, when that load is active while other loads in the circuit are inactive. Then any reading >0 Amps would provide the user with this information as a current would be flowing through the particular load. In complex automated power systems, such as Eaton's PowerGenome, this is more complicated due to the number of electrical loads within the circuit and the amount of data that can be collected. However, the present disclosure addresses this issue, providing the user with extensive and detailed system information.

Once a difference has been detected in the power time-series that meets the conditions of the threshold, that event is attributed a timestamp. For example, if the signal is found to exceed the threshold, i.e. >10 Amps, that event is assigned a timestamp to match the signal data to the time that event happened. The timestamped data is then stored in a timestamp datastore. If the difference in the power does not meet the conditions of the event threshold, the process at 302 of the flow diagram 300 repeats until another event is detected. Depending on the application this may be a continuous cycle over the lifetime of the load, or may be for a fixed time interval selected by the user, i.e. over a few hours or days or the like. For example, the time interval can be selected according to the timing sequences conditions of the automated power system which would have been programmed by the user using the PLC programming.

The third step 303 of the method, as illustrated by the flow diagram 300 in FIG. 3, is to disaggregate and identify the electrical load based on the collated data, as stored in the datastore(s). The collated data is used to determine the power signature and load profile of one or more loads within the time-series. One of the new timestamp events is selected from the event timestamp datastore and nearest neighbour comparison is performed to each timing sequence (N sequences) available within the timing sequence datastore. The nearest neighbour analysis is performed until the closest timing sequence is found to correlate with the event timestamp. Once the timestamp and timing sequence are mapped the load can be classified by the relationship between the timing sequence and the load, according to the ladder logic programming. For example, if an event occurred at or near the same time as the output of a particular load was executed in the ladder logic program, then the event can be assigned to that load. A classification threshold is used to avoid spurious associations and false assignments. The mapped profile of the load is then stored in a load profile datastore. The load profile data can be used for load monitoring, digital health, device diagnostics, power optimisation purposes and the like. Again, all the datastores (timing sequence, event timestamp and load profile) may be located locally on the automated control management system or the data may be transmitted to datastores of a remote server (or cloud), allowing remote access and analysis.

As discussed above, this disaggregation and identification process may be applied to a domestic power system. The “timing sequence” data may be collated from an application which controls the IoT appliances and devices within the home. This information can be stored locally on a device, such as a mobile, tablet or laptop device, etc, or remotely in a remote datastore of a remote or cloud server. The power time-series data can be measured via the sensors within circuit breakers of the appliances and devices and transmitted by WIFI, or other network protocols, to a local device or a remote datastore. The mapping of the measured event and the timing sequence can also take place in an application on a local device or may be performed remotely. The ability to perform the process locally allows the home owner to monitor and optimise their appliances and devices for their needs. Having remote access allows third parties, such as energy companies, to monitor and analyse the data.

1. A disaggregation and identification method arranged to disaggregate and identify aggregated electrical load data, comprising the steps of:
obtaining operation data from an automated control management system;
extracting a timing sequence from the operation data for each load in the automated system;
storing each timing sequence in a datastore;
streaming aggregated power data from a load center associated with the system, wherein the power data comprises measured electrical signals;
recording time stamps for each new event measured from the streamed aggregated power data, wherein an event is a change in power signal at a load;
performing nearest neighbour comparison of the recorded power time series data to the timing sequence of the operation data;
mapping each event timestamp to the nearest time sequence;
classifying the load according to the mapped time data; and,
storing the classified load profile in a datastore.

2. The method of claim 1, wherein the automated control management system is a ladder logic program, controlling a plurality of programmable logic controllers.

3. The method of claim 1, wherein the loads are controlled from the load center based on an automated schedule of aggregated signals.

4. The method of claim 1, wherein the load center is connected to a plurality of loads connected to the same circuit.

5. The method of claim 1, wherein the loads are associated with industrial or domestic devices.

6. The method of claim 1, wherein the load center captures the current and voltage signals of the connected loads.

7. The method of claim 1, wherein each recorded event is within an event threshold.

8. The method of claim 1, wherein a classification threshold is used to avoid spurious associations.

9. The method of claim 1, wherein the datastore is located locally at system level.

10. The method of claim 1, wherein the datastore is located remotely on a remote server or cloud, or the like.

11. The method of claim 1, wherein the load profiles are analyzed at the time of acquisition or at a later date.

12. A disaggregation and identification system, comprising:
a processor;
an automated control management system;
a load center; and,
a datastore,
wherein the processor is configured to disaggregate and identify load data from an aggregated electrical signal using the method of claims 1.
